(19) United States
(12) Patent Application Publication
(10) Pub. No.: US 2008/0018498 A1
(43) Pub. Date: Jan. 24, 2008

(54) Message generating apparatus

(75) Inventors: Hung-Chi Huang, Taipei (TW); Chih-Wen Ko, Taipei (TW)

Correspondence Address: REED SMITH LLP, Suite 1400, 3110 Fairview Park Drive, Falls Church, VA, 22042, US

(73) Assignee: Compal Communications, Inc.

(21) Appl. No.: 11/878,104

(22) Filed: Jul. 20, 2007

(30) Foreign Application Priority Data
Jul. 21, 2006 (TW) 095126857

(51) Int. Cl. H03K 17/94

(52) U.S. Cl. 341/21; 379/52

(57) ABSTRACT

The invention provides a message generating apparatus for an electronic equipment. The message generating apparatus includes a look-up table, a first/sucked device, a pressure-sensing device, a processing module, and an interface module. The first/sucked device accommodates a liquid. The pressure-sensing device is installed inside or outside the first/sucked device. The processing module is electrically connected to the look-up table and the pressure-sensing device respectively. The interface module is electrically connected to the processing module, and capable of connecting to an input port of the electronic equipment. The pressure-sensing device senses a pressure of the liquid, and generates a pressure signal in response to the sensed pressure. The processing module determines one of the messages in accordance with the pressure signal and the look-up table, and transmits the determined message through the interface module to the input port.

### BACKGROUND OF THE INVENTION

1. Field of the Invention

The present invention relates to a message generating apparatus, and more particularly, relates to a message generating apparatus sensing a pressure of a liquid.

2. Description of the Prior Art

So far the input system of common electronic equipment uses a manual input or a voice control input. These methods are acceptable to a normal person, but it is doubtful whether they are acceptable to body disability or deaf-and-dumb persons. Especially for persons with body disabilities or under these situations, because they have inputting disability, obviously, the conventional input method can not provide efficient and practical input solution. In most situations, for people who has body disabilities or who are in these situations or people, the mouth function thereof still works well, or the body thereof can perform limited motion. If the input can be performed by a mouth or a body capable of moving limitedly, a baby who can not freely use his hands or a person with disability can express many messages by mouth gnawing, sucking, or limited body motions for the purpose of communicating with the external world.

Accordingly, a scope of the invention is to provide a character generating apparatus which produces a liquid pressure by gnawing, sucking, or limited body motions and then senses the pressure, so as to solve the problem mentioned above.

### SUMMARY OF THE INVENTION

A scope of the invention provides a character generating apparatus which produces a liquid pressure by gnawing, sucking, or limited body motions and then senses the pressure.

According to a preferred embodiment, a message generating apparatus of the invention includes a look-up table, a first/sucked device, a pressure-sensing device, a transmission cable, a processing module, and an interface module. The look-up table records a plurality of first pressure signals and a plurality of messages. Each of the first pressure signals corresponds to one of the messages. The first/sucked device accommodates a liquid. The pressure-sensing device installed inside or outside the first/sucked device. The processing module is electrically connected to the look-up table and is connected to the pressure-sensing device through the transmission cable. The length of the transmission cable depends on an actual application. The interface module is electrically connected to the processing module. The interface module is capable of connecting to an input port of an electronic equipment. According to the preferred embodiment, the liquid accommodated by the first/sucked device is a saline solution. The pressure-sensing device includes an induction coil for sensing a pressure of the saline solution. The interface module is configured to comply with a universal serial bus standard.

Furthermore, when a user gnaws, sucks, or presses by use of his body the first/sucked device such that the first/sucked device deforms, the force loaded by the user by gnawing, sucking, or pressing by use of his body is transmitted to the saline solution through the first/sucked device to be presented in the pressure of the saline solution. The pressure-sensing device senses a pressure of the saline solution and generates a second pressure signal in response to the sensed pressure of the saline solution. The processing module receives the second pressure signal from the pressure-sensing device, judges whether the second pressure signal matches one of the first pressure signals, and if yes, determines one of the messages according to the matched first pressure signal. The processing module transmits the determined message through the interface module to the input port.

Therefore, by properly designing the look-up table, a user can express different messages by gnawing, sucking, or pressing by use of his body the first/sucked device of the message generating apparatus of the invention, so as to achieve the purpose of communicating with the external world.

The advantage and spirit of the invention may be further understood by the following recitations together with the appended drawings.

### BRIEF DESCRIPTION OF THE APPENDED DRAWINGS

FIG. 1 is a sketch diagram illustrating a first preferred embodiment according to the invention.

FIG. 2 is a sketch diagram illustrating a second preferred embodiment according to the invention.

### DETAILED DESCRIPTION OF THE INVENTION

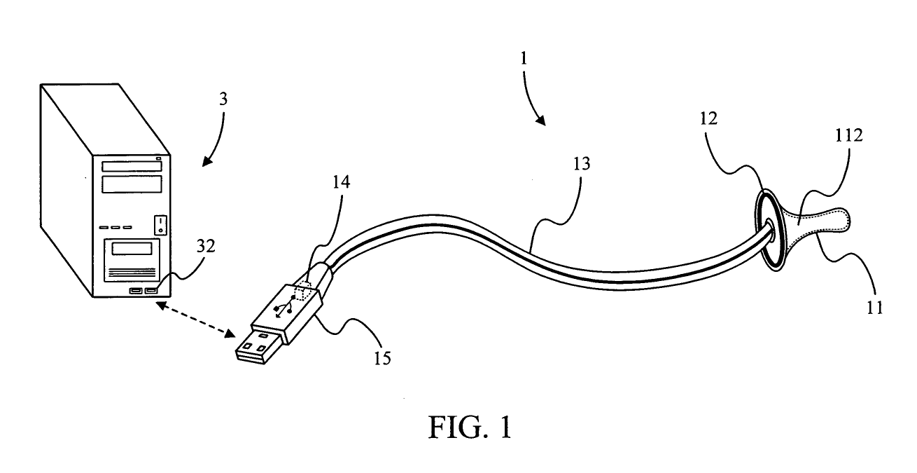

Please refer to FIG. 1. FIG. 1 is a sketch diagram illustrating a first preferred embodiment according to the invention. According to the first preferred embodiment, a message generating apparatus 1 of the invention includes a look-up table, a first device 11, a pressure-sensing device 12, a transmission cable 13, a processing module 14, and an interface 15. The look-up table records a plurality of first pressure signals and a plurality of messages. Each of the first pressure signals corresponds to one of the messages. The first device 11 accommodates a liquid 112. The pressure-sensing device 12 is installed inside the first device 11. The processing module 14 is electrically connected to the look-up table and is connected through the transmission cable 13 to the pressure-sensing device 12. The length of the transmission cable 13 depends on the actual application. The interface module 15 is electrically connected to the processing module 14. The interface module 15 is capable of connecting to an input port 32 (shown in dashed line) of an electronic equipment 3. According to the first preferred embodiment, the liquid 112 accommodated by the first device 11 is saline solution. The pressure-sensing device 12 includes an induction coil for sensing a pressure of the saline solution 112. The interface module 15 is configured to comply with a universal serial bus standard.

When a user gnaws, sucks, or presses by use of his body the first device 11 such that the first device 11 deforms, the force loaded by the user by gnawing, sucking, or pressing by use of his body is transmitted to the saline solution 112 through the first/sucked device 11 to be presented in the pressure of the saline solution 112. It is an additional remark that the material of the part of the first device 11 gnawed, sucked, or pressed by use of his body is usually made of elastic material or plastic material, such as silicone. When the user gnaws, sucks, or presses by use of his body the first device 11, the part gnawed, sucked, or pressed by use of his body deforms, the capacity of the first device 11 for accommodating the saline solution 112 decreases so as to compress the saline solution 112, such that the pressure of the saline solution 112 increases due to the compression. Therefore, the force loaded by the user by gnawing, sucking, or pressing by use of his body is presented in the pressure of the saline solution 112. That is, in a normal situation, if the loaded force is larger, the pressure of the saline solution 112 is also larger; if the loaded force is smaller, the pressure of the saline solution 112 is also smaller.

According to the first preferred embodiment, the pressure-sensing device 12 senses the pressure of the saline solution 112 and generates a second pressure signal in response to the sensed pressure of the saline solution 112. The processing module 14 receives the second pressure signal from the pressure-sensing device 12, judges whether the second pressure signal matches one of the first pressure signal, and if yes, determines one of the messages according to the matched first pressure signal. The processing module 14 transmits the determined message through the interface module 15 to the input port 32.

Therefore, according to the first preferred embodiment, the message generating apparatus 1 of the invention can express different messages by gnawing, sucking, or pressing by use of body the first device 11.

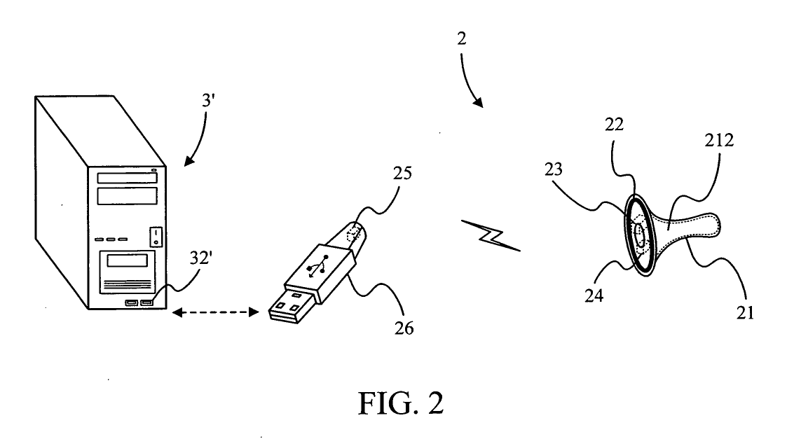

Please refer to FIG. 2. FIG. 2 is a sketch diagram illustrating a second preferred embodiment according to the invention. According to the second preferred embodiment, a message generating apparatus 2 includes a look-up table, a sucked device 21, a pressure-sensing device 22, a processing module 23, a transmitting module 24, a receiving module 25, and an interface module 26. The look-up table records a plurality of first pressure signals and a plurality of messages. Each of the first pressure signals corresponds to one of the messages. The sucked device 21 accommodates a liquid 212. The pressure-sensing device 22 is installed inside the sucked device 21. The processing module 23 is electrically connected to the look-up table, the pressure-sensing device 22, and the transmitting module 24 respectively. The interface module 26 is electrically connected to the receiving module 25. The interface module 26 is capable of connecting to an input port 32′ (shown in dashed line) of an electronic equipment 3′. The transmitting module 24 and the receiving module 25 communicate in a wireless mode. According to the second preferred embodiment, the liquid 212 accommodated by the sucked device 21 is a saline solution. The pressure-sensing device 22 includes an induction coil for sensing a pressure of the saline solution 212. The interface module 26 is configured to comply with a universal serial bus standard. In addition, the relation between the pressure of the saline solution 212 and the motions of gnawing or sucking the sucked device 21 is the same as the description in the first preferred embodiment and will not be described here.

Furthermore, the pressure-sensing device 22 senses the pressure of the saline solution 212 and generates a second pressure signal in response to the sensed pressure of the saline solution 212. The processing module 23 receives the second pressure signal from the pressure-sensing device 22, judge whether the second pressure signal matches one of the first pressure signals, and if yes, determines one of the messages according to the matched first pressure signal. The determined message is transmitted in the wireless mode by the transmitting module 24, then is received by the receiving module 25, and finally is transmitted through the interface module 26 to the input port 32′.

Therefore, according to the second preferred embodiment, the message generating apparatus 2 of the invention can express different message by gnawing or sucking the sucked device 21 and can be applied for a wider operation space. For example, the sucked device 21 of the message generating apparatus 2 can be operated by a patient in a sickroom, and the electronic equipment 3′ is in a nursing station beyond ten meters.

In addition, in the above preferred embodiments, the interface module is configured to comply with a recommend standard-232 and an institute of electrical and electronic engineers 1394 standard.

It should be noticed that, in the above preferred embodiments, the pressure-sensing device can use, except an induction coil, at least one strain gauge, mechanical pressure switch, or other devices directly or indirectly sensing the pressure of the liquid. Moreover, the second pressure signal is not limited to a single signal and can also be a compound signal. For example, if the pressure-sensing device includes a plurality of strain gauges, the first/sucked device deforms due to the gnawing, the sucking, or the pressing by use of body, such that the strain gauges generate different sensed signals. These sensed signals form a compound signal transmitted to the processing module. In addition, the messages recorded in the look-up table are not limited to the expression of the user, and they also can be command messages which the electronic equipment responds to. For example, a patient can order the electronic equipment to control the drop flow or increase or decrease the dosage by special gnawing or sucking the first/sucked device. Furthermore, the method or format of physically transmitting the transmitted messages in the preferred embodiments depends on the used transmission media and the transmission protocols, which belongs to relative prior arts and will not be described more here. Moreover, the format and the content of the data corresponding to the message can be determined by a protocol existing both in the processing module and the electronic equipment, which belongs to relative prior arts and will not be described more here. For example, a message is “increase light”, of which the content and the format of the data transmitted in physical can be four characters—AB07, and the data is then added with the necessary header and/or trail based on the protocol to be digitally transmitted through a serial port.

With the recitations of the preferred embodiment above, the features and spirits of the invention will be hopefully well described. However, the scope of the invention is not restricted by the preferred embodiment disclosed above. The objective is that all alternative and equivalent arrangements are hopefully covered in the scope of the appended claims of the invention. Accordingly, the above disclosure should be construed as limited only by the metes and bounds of the appended claims.

What is claimed is:

1. A message generating apparatus for an electronic equipment with an input port, said message generating apparatus comprising:
a look-up table recording a plurality of first pressure signals and a plurality of messages, each of the first pressure signals corresponding to one of the messages;
a first device accommodating a liquid;
a pressure-sensing device for sensing a pressure of the liquid and generating a second pressure signal in response to the sensed pressure, the pressure-sensing device being installed on the first device;
a processing module electrically connected to the look-up table and the pressure-sensing device respectively, the processing module receiving the second pressure signal from the pressure-sensing device, judging whether the second pressure signal matches one of the first pressure signals, and if yes, determining one of the messages according to the matched first pressure signal; and
an interface module electrically connected to the processing module, the interface module being capable of connecting to the input port of the electronic equipment, the processing module transmitting the determined message through the interface module to the input port.

2. The message generating apparatus of claim 1, wherein the first device is capable of being sucked, gnawed, or body pressure.

3. The message generating apparatus of claim 1, wherein the pressure-sensing device is installed inside or outside the first device.

4. The message generating apparatus of claim 1, wherein the input port is configured to comply with one selected from the group consisting of a universal serial bus standard, a recommend standard-232, and an institute of electrical and electronic engineers 1394 standard.

5. The message generating apparatus of claim 1, wherein the first device is a sucked device.

6. A message generating apparatus for an electronic equipment with an input port, said message generating apparatus comprising:
a look-up table recording a plurality of first pressure signals and a plurality of messages, each of the first pressure signals corresponding to one of the messages;
a first device accommodating a liquid;
a pressure-sensing device for sensing a pressure of the liquid and generating a second pressure signal in response to the sensed pressure, the pressure-sensing device being installed on the first device;
a processing module electrically connected to the look-up table and the pressure-sensing device respectively, the processing module receiving the second pressure signal from the pressure-sensing device, judging whether the second pressure signal matches one of the first pressure signals, and if yes, determining one of the messages according to the matched first pressure signal;
a transmitting module electrically connected to the processing module, the transmitting module transmitting the determined message in a wireless mode;
a receiving module for receiving the determined message transmitted from the transmitting module; and
an interface module electrically connected to the receiving module, the interface module being capable of connecting to the input port of the electronic equipment, the determined message received by the receiving module being transmitted through the interface module to the input port.

7. The message generating apparatus of claim 6, wherein the first device is capable of being sucked, gnawed, or body pressure.

8. The message generating apparatus of claim 6, wherein the pressure-sensing device is installed inside or outside the first device.

9. The message generating apparatus of claim 6, wherein the input port is configured to comply with one selected from the group consisting of a universal serial bus standard, a recommend standard-232, and an institute of electrical and electronic engineers 1394 standard.

10. The message generating apparatus of claim 6, wherein the first device is a sucked device.
